(19) United States
(12) Patent Application Publication
(10) Pub. No.: US 2026/0068595 A1
(43) Pub. Date: Mar. 5, 2026

(54) MANUFACTURING METHOD OF SEMICONDUCTOR DEVICE USING DICING TAPE, AND DICING TAPE

(71) Applicants: KABUSHIKI KAISHA TOSHIBA, Kawasaki-shi (JP); Toshiba Electronic Devices & Storage Corporation, Kawasaki-shi (JP)

(72) Inventors: Yuma YAMASHITA, Yokohama Kanagawa (JP); Kenichi OOHASHI, Kawasaki Kanagawa (JP); Kentaro MORI, Fujisawa Kanagawa (JP); Kazushiro NOMURA, Kawasaki Kanagawa (JP)

(73) Assignees: KABUSHIKI KAISHA TOSHIBA, Kawasaki-shi (JP); Toshiba Electronic Devices & Storage Corporation, Kawasaki-shi (JP)

(21) Appl. No.: 19/319,854

(22) Filed: Sep. 5, 2025

(30) Foreign Application Priority Data
Sep. 5, 2024 (JP) 2024-153207

(51) Int. Cl. H01L 21/683; H01L 21/78

(52) U.S. Cl. CPC H01L 21/6836

(57) ABSTRACT

According to one embodiment, a manufacturing method of a semiconductor device, comprising: attaching a dicing tape to a ring frame, the dicing tape including a base, an adhesive provided on an upper surface of the base and including a material capable of changing in property by light irradiation, and a releasing film; executing light irradiation from below the base, thereby making an adhesivity of a first portion overlapping the releasing film, in an upper surface of the adhesive, different from an adhesivity of a second portion not overlapping the first portion, in the upper surface of the adhesive; attaching a work piece to the adhesive; and singulating a plurality of semiconductor devices by dicing the work piece.

### CROSS-REFERENCE TO RELATED APPLICATION

This application is based upon and claims the benefit of priority from prior Japanese Patent Application No. 2024-153207, filed Sep. 5, 2024, the entire contents of which are incorporated herein by reference.

### FIELD

Embodiments described herein relate generally to a manufacturing method of a semiconductor device using a dicing tape, and a dicing tape.

### BACKGROUND

At a time of dicing a wafer on which a plurality of semiconductor devices are formed, the wafer is fixed on a ring frame via a dicing tape. Then, the semiconductor devices are singulated by separating the fixed wafer by dicing using a blade.

### BRIEF DESCRIPTION OF THE DRAWINGS

FIG. 1 is a cross-sectional view illustrating an example of a dicing tape according to an embodiment.

FIG. 2 is a top view illustrating an example of the dicing tape according to the embodiment.

FIG. 3 is a cross-sectional view for describing a manufacturing method of a semiconductor device using the dicing tape according to the embodiment.

FIG. 4 is a top view for describing the manufacturing method of the semiconductor device using the dicing tape according to the embodiment.

FIG. 5 is a cross-sectional view for describing the manufacturing method of the semiconductor device using the dicing tape according to the embodiment.

FIG. 6 is a top view for describing the manufacturing method of the semiconductor device using the dicing tape according to the embodiment.

FIG. 7 is a cross-sectional view illustrating an example of a dicing tape according to a modification.

FIG. 8 is a bottom view illustrating an example of the dicing tape according to the modification.

FIG. 9 is a cross-sectional view for describing a manufacturing method of a semiconductor device using the dicing tape according to the modification.

FIG. 10 is a top view for describing the manufacturing method of the semiconductor device using the dicing tape according to the modification.

FIG. 11 is a cross-sectional view for describing the manufacturing method of the semiconductor device using the dicing tape according to the modification.

FIG. 12 is a top view for describing the manufacturing method of the semiconductor device using the dicing tape according to the modification.

### DETAILED DESCRIPTION

In general, according to one embodiment, a manufacturing method of a semiconductor device, comprising: attaching a dicing tape to a ring frame, the dicing tape including a base, an adhesive provided on an upper surface of the base and including a material capable of changing in property by light irradiation, and a releasing film provided in such a manner as to overlap a portion of the adhesive as viewed from above; executing light irradiation from below the base, thereby making an adhesivity of a first portion overlapping the releasing film as viewed from above, in an upper surface of the adhesive, different from an adhesivity of a second portion not overlapping the first portion, in the upper surface of the adhesive; attaching a work piece to the adhesive by making a center of the work piece correspond to a center of an area where the releasing film is provided in the dicing tape; and singulating a plurality of semiconductor devices by dicing the work piece.

Hereinafter, an embodiment is described with reference to the accompanying drawings. The dimensions and radios in the drawings are not necessarily identical to real ones.

In the description below, structural elements having substantially identical functions and structures are denoted by like reference signs. In a case where elements having similar structures are particularly distinguished, mutually different characters or numerals may be added to the end of an identical reference sign.

### 1. Embodiment

Hereinafter, a dicing tape according to an embodiment is described.

In the description below, a wafer that is a target of dicing using a dicing tape is referred to as “work” or “work piece”. In addition, a direction in a plane of the dicing tape is referred to as “X direction”. A direction perpendicular to the X direction in the plane is referred to as “Y direction”. A direction perpendicular to the plane is referred to as “Z direction”. In addition, in the dicing tape, between a side on which a work is fixed at a time of dicing and a side on which a ring frame is disposed at the time of dicing, the side on which the work is fixed is referred to as “upper side”. In the dicing tape, between the side on which the work is fixed and the side on which the ring frame is disposed, the side on which the ring frame is disposed is referred to as “lower side”. Besides, in the dicing tape, between a surface on the side on which the work is fixed and a surface on the side on which the ring frame is disposed, the surface on the side on which the work is fixed is referred to as “upper surface”. In the dicing tape, between the surface on the side on which the work is fixed and the surface on the side on which the ring frame is disposed, the surface on the side on which the ring frame is disposed is referred to as “lower surface” or “back surface”.

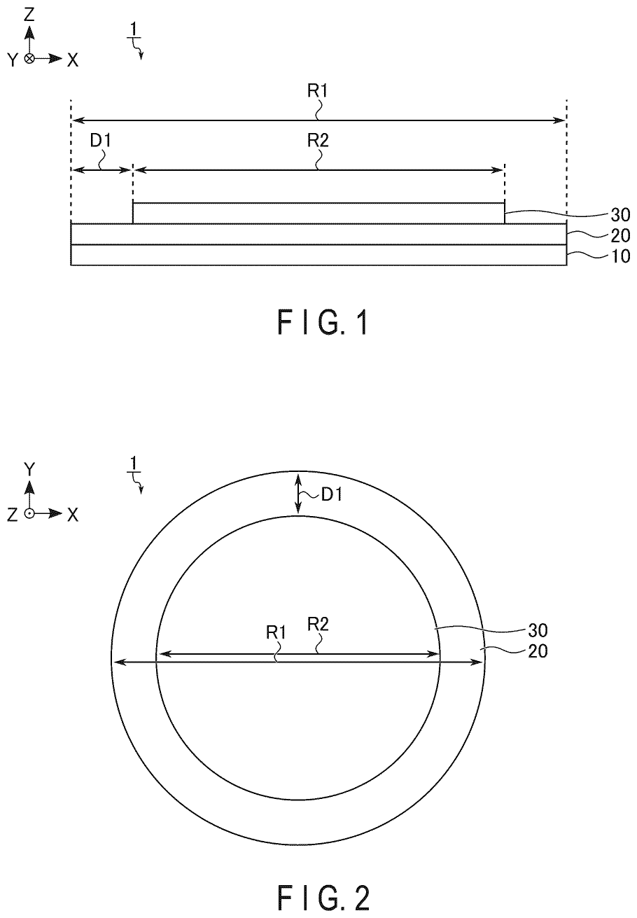

A configuration of the dicing tape according to the embodiment is described with reference to FIG. 1 and FIG. 2. FIG. 1 is a cross-sectional view illustrating an example of the dicing tape according to the embodiment. The cross-sectional view of FIG. 1 is a cross-sectional view in an XZ cross section. In addition, FIG. 2 is a top view illustrating an example of the dicing tape according to the embodiment.

A dicing tape 1 includes a base 10, an adhesive 20, and a releasing film 30.

The base 10 is formed of a material having expandability. The material includes, for example, polyolefin. The base 10 has, for example, light transmissivity with respect to light such as ultraviolet (UV light). The base 10 has, for example, a circular shape as viewed from above. A diameter of the base 10 as viewed from above is a length R1. The length R1 is greater than a length RW of a diameter of the work to be diced (RW<R1).

The adhesive 20 is provided on an upper surface of the base 10. The adhesive 20 includes a material that changes in property by a curing reaction by light irradiation by a laser, a lamp or the like. The light by the laser, lamp or the like is, for example, ultraviolet. Specifically, the material is a UV-curing material. The adhesive strength of the material decreases as the curing reaction progresses. The curing reaction of the material is affected by a reaction hindrance by oxygen. Thereby, for example, a portion of the surface of the adhesive 20, which is in contact with a region including oxygen, has a lower curing reaction rate of the material than a portion of the surface of the adhesive 20, which is in contact with a region having a lower oxygen concentration than the above-described portion. The adhesive material 20 has, for example, a circular shape as viewed from above. A diameter of the adhesive 20 as viewed from above is substantially equal to, for example, a diameter of the base 10.

The releasing film 30 is provided on the upper surface of the adhesive 20. The releasing film 30 has non-adhesivity. The releasing film 30 is configured to be peelable from the upper surface of the adhesive 20. The releasing film 30 has, for example, a circular shape as viewed from above. A diameter of the releasing film 30 as viewed from above is a length R2. The length R2 is less than the length RW (R2<RW). A difference between the length R2 and the length RW is, for example, 2 mm or more, and is 30 mm or less (2 mm≤(RW−R2)≤30 mm). By the above configuration, the upper surface of the adhesive 20 includes a first portion that is in contact with the lower surface of the releasing film 30, and a second portion that is not in contact with the lower surface of the releasing film 30. By this configuration, the releasing film 30 is configured such that the contact between the upper surface of the adhesive 20 and oxygen is more suppressed in the first portion than in the second portion. As viewed from above, the second portion has, for example, an annular shape (donut shape) that is in rotation symmetry with respect to the Z axis. In the Y direction, a distance D1 from one end or the other end of the adhesive 20 to one end or the other end of the releasing film 30 is, for example, about 20 mm. Also in the X direction, a distance from one end or the other end of the adhesive 20 to one end or the other end of the releasing film 30 is, for example, about 20 mm.

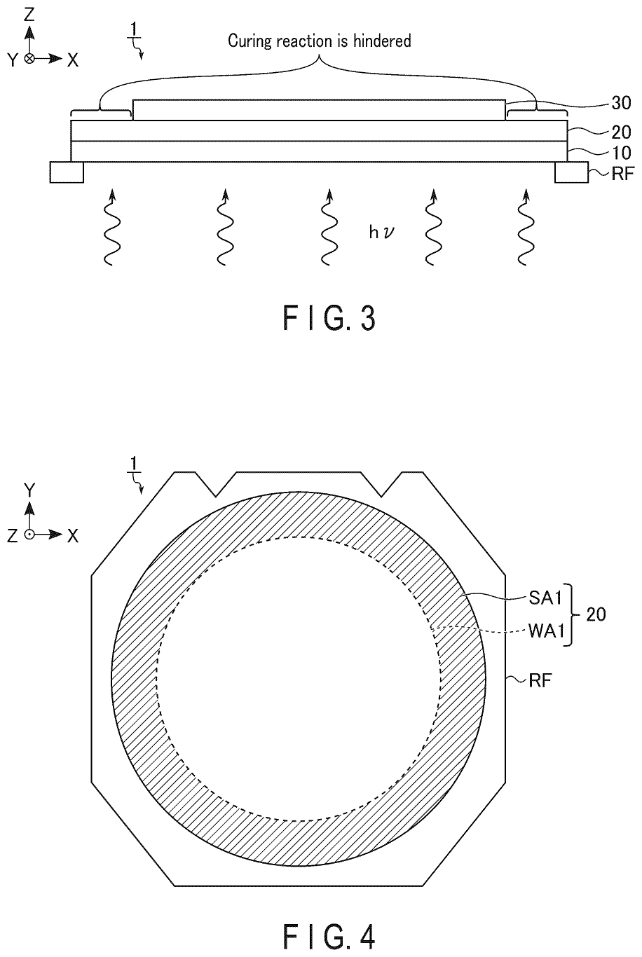

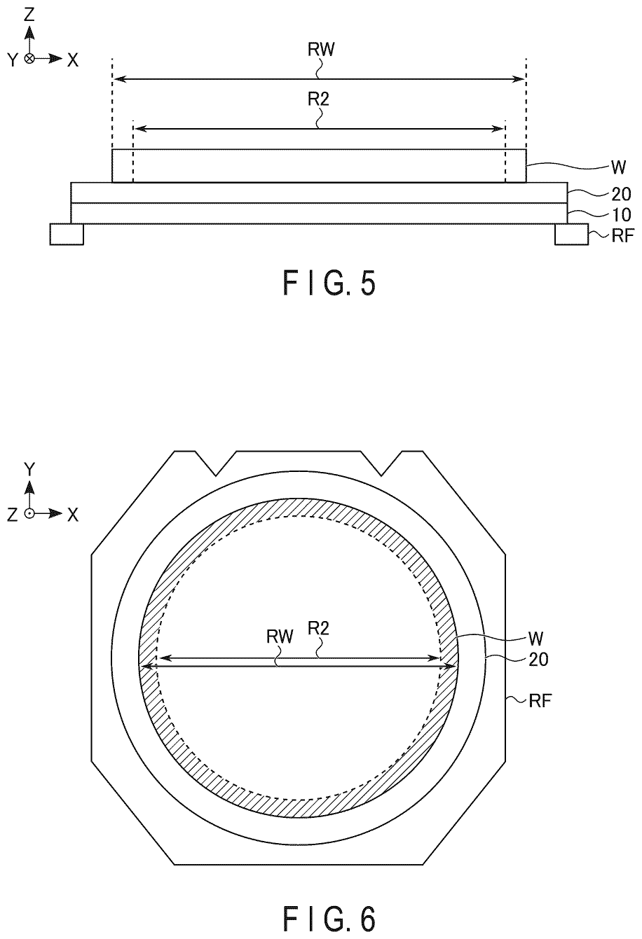

Next, a manufacturing method of a semiconductor device using the dicing tape 1 according to the embodiment is described with reference to FIG. 3, FIG. 4, FIG. 5 and FIG. 6. FIG. 3 and FIG. 5 are cross-sectional views for describing the manufacturing method of the semiconductor device using the dicing tape according to the embodiment. FIG. 3 and FIG. 5 correspond to the cross-sectional view of FIG. 1. FIG. 4 and FIG. 6 are top views for describing the manufacturing method of the semiconductor device using the dicing tape according to the embodiment.

To start with, the dicing tape 1 is attached to a ring frame RF. At this time, the dicing tape 1 is attached such that a back surface of the dicing tape 1 comes in contact with the ring frame RF. Specifically, a lower surface of the base 10 of the dicing tape 1 comes in contact with the ring frame RF.

Then, for example, as illustrated in FIG. 3, UV light irradiation, such as by a laser or a lamp, is executed from the back side of the dicing tape 1 attached to the ring frame RF, toward a region where the releasing film 30 is provided. By the execution of the light irradiation, the adhesivity of the first portion overlapping the releasing film 30, in the upper surface of the adhesive 20, is made different from the adhesivity of the second portion not overlapping the releasing film 30, in the upper surface of the adhesive 20. The step of executing the light irradiation is described more specifically. This step is executed in an atmosphere in which oxygen is present, such as in an air atmosphere. In FIG. 3, the light irradiation is indicated by “hv”. By the above-described light irradiation, a curing reaction of the adhesive 20 progresses. At this time, in the second portion of the adhesive 20, which is not in contact with the lower surface of the releasing film 30, the curing reaction progresses slower than in the first portion of the adhesive 20, which is in contact with the lower surface of the releasing film 30, by the hindrance of the reaction due to oxygen. Thus, by the light irradiation, the adhesive strength in the second portion is made higher than the adhesive strength in the first portion. In other words, a portion with a low adhesive strength and a portion with a high adhesive strength are formed in the adhesive 20. Note that in the above-described step, the portion with the lower adhesive strength of the adhesive 20 may be formed as a non-adhesive portion.

Then, after the light irradiation, the releasing film 30 is peeled from the adhesive 20. Thereby, the upper surface of the adhesive 20 is entirely exposed. Thus, as illustrated in FIG. 4, a portion WAL with a low adhesive strength and a portion SA1 with a high adhesive strength are exposed. The portion WAL and the portion SA1 correspond to the first portion and the second portion of the adhesive 20, respectively. In FIG. 4, the portion SA1 is illustrated by hatching.

In addition, as illustrated in FIG. 5, a work W on which a plurality of semiconductor devices are formed is fixed on the adhesive 20 on which the portions WAL and SA1 are exposed. At this time, the work W is attached on the adhesive 20 such that the center of the work W (the center of a semiconductor substrate of the work W) corresponds to the center of the area from which the releasing film 30 is peeled. To make the center of the work W correspond to the center of the area from which the releasing film 30 is peeled includes to make the two centers coincide, as viewed from above, and includes to dispose the two centers at a substantially identical position. As described above, the length R2 is less than the length RW that is the diameter of the work W. Thereby, as illustrated in FIG. 6, the work W is fixed such that the lower surface of the work W covers the entirety of the portion WAL with the low adhesive strength. In addition, the work W is fixed such that an outer peripheral portion of the work W, as viewed from above, comes in contact with the portion SA1 with the high adhesive strength in an annular shape. In FIG. 6, the outer peripheral portion of the work W, which is in contact with the portion SA1, is illustrated by hatching.

Then, the work W fixed on the adhesive 20 as described above is diced by a blade or the like. Thereby, the semiconductor devices are singulated.

According to the embodiment, a high-quality semiconductor device can be provided, while chip fly-off at the outermost peripheral portion of the work is being suppressed.

The dicing tape 1 according to the embodiment includes the base 10, adhesive 20 and releasing film 30. The adhesive 20 is provided on the upper surface of the base 10. The adhesive 20 includes a material capable of changing in property by light irradiation by a laser, a lamp or the like. The releasing film 30 is configured to be peelable. In addition, the outside diameter of the releasing film 30, as viewed from above, is less than the outside diameter of the work W. At the time of dicing of the work W, the portion SA1 with the high adhesive strength and the portion WA1 with the low adhesive strength are formed on the upper surface of the adhesive 20 by the photo-curing reaction hindrance using the releasing film 30 at a time of the light irradiation. By attaching the work W to the adhesive 20 on which the portions SA1 and WAL are formed, a high-quality semiconductor device can be provided while chip fly-off at the outermost peripheral portion of the work is being suppressed.

Regarding the above, a supplementary description is given. In the dicing using a blade, at a time of cutting a circular work, a substantially triangular semiconductor substrate (a chip that is not rectangular), which is smaller than a chip size of a semiconductor device, is formed at the outermost peripheral portion of the work. In a case where a dicing tape including an adhesive with a low adhesive strength is used, such a substantially triangular semiconductor substrate may peel and fly off. This is called “chip fly-off”. In the dicing, there is a problem that the blade is broken by such chip fly-off. As a solution to this problem, there is a case of increasing the adhesive strength of the dicing tape provided on the base. However, in this case, since the adhesive of the dicing tape becomes softer as a whole, for example, there is a case where when a work having a back surface provided with a metal is diced, burrs of the metal on the back surface, which occur due to dicing, bite into the dicing tape. Thereby, it may become difficult to pick up a semiconductor device that is cut. Thus, a deterioration in quality of a semiconductor device at a time of picking up may occur.

According to the embodiment, as illustrated in FIG. 6, at the time of dicing, while the outer peripheral portion of the work W is fixed by the portion SA1 with the high adhesive strength, the part excluding the outer peripheral portion of the work W is fixed by the portion WAL with the low adhesive strength. Thereby, at the outer peripheral portion of the work W, the substantially triangular semiconductor substrate that occurs after dicing can be kept in the fixed state to the adhesive 20, and the chip fly-off can be suppressed. Furthermore, at the part excluding the outer peripheral portion of the work W on which semiconductor devices are formed, burrs occurring on the back surface of the work W can be prevented from biting into the dicing tape 1. As described above, according to the embodiment, while the chip fly-off is being suppressed, the cut semiconductor device can easily be picked up, and the deterioration in quality of the semiconductor device can be suppressed.

### 2. Modification

Next, a semiconductor device according to a modification is described. Hereinafter, the configuration of the semiconductor device according to the modification is described mainly on different points from the configuration of the semiconductor device according to the embodiment. A description of a common configuration to the embodiment is omitted unless otherwise necessary.

A dicing tape according to the modification is different from the embodiment, in that a releasing film is provided on the lower surface side of the base of the dicing tape.

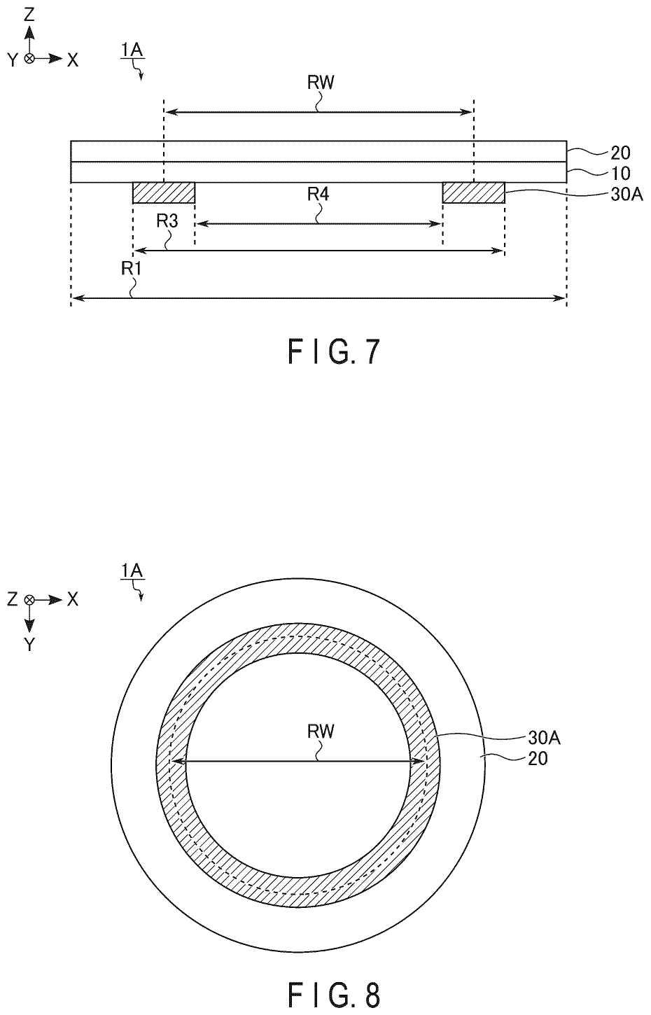

To begin with, the configuration of the dicing tape according to the modification is described with reference to FIG. 7 and FIG. 8. FIG. 7 is a cross-sectional view illustrating an example of the dicing tape according to the modification. The cross-sectional view of FIG. 7 is a cross-sectional view in an XZ cross section. FIG. 8 is a bottom view illustrating an example of the dicing tape according to the modification.

A dicing tape 1A according to the modification includes a base 10, an adhesive 20, and a releasing film 30A.

The releasing film 30A is provided in such a manner as to come in contact with the lower surface of the base 10. The releasing film 30A has non-adhesivity. The releasing film 30A is configured to be peelable from the lower surface of the base 10. The releasing film 30A has a light-shielding property with respect to light used in a curing reaction of the adhesive 20. The releasing film 30A has, for example, an annular configuration that is in rotation symmetry with respect to the Z axis. A length R3 of the outside diameter of the releasing film 30A is, for example, greater than the length RW of the work W, and is equal to or less than the length R1 of the base 10 (RW<R3≤R1). A length R4 of the inside diameter of the releasing film 30A is less than the length RW of the work W (R4<RW). A difference between the length R4 and the length RW is, for example, 4 mm or more (4 mm≤(RW−R4)). By the above configuration, the adhesive 20 includes a third portion that does not overlap the releasing film 30A in the Z direction, and a fourth portion that overlaps the releasing film 30A in the Z direction. The third portion includes, for example, as viewed from above, a portion inside the fourth portion, and a portion outside the fourth portion. Note that the third portion may not include the portion outside the fourth portion.

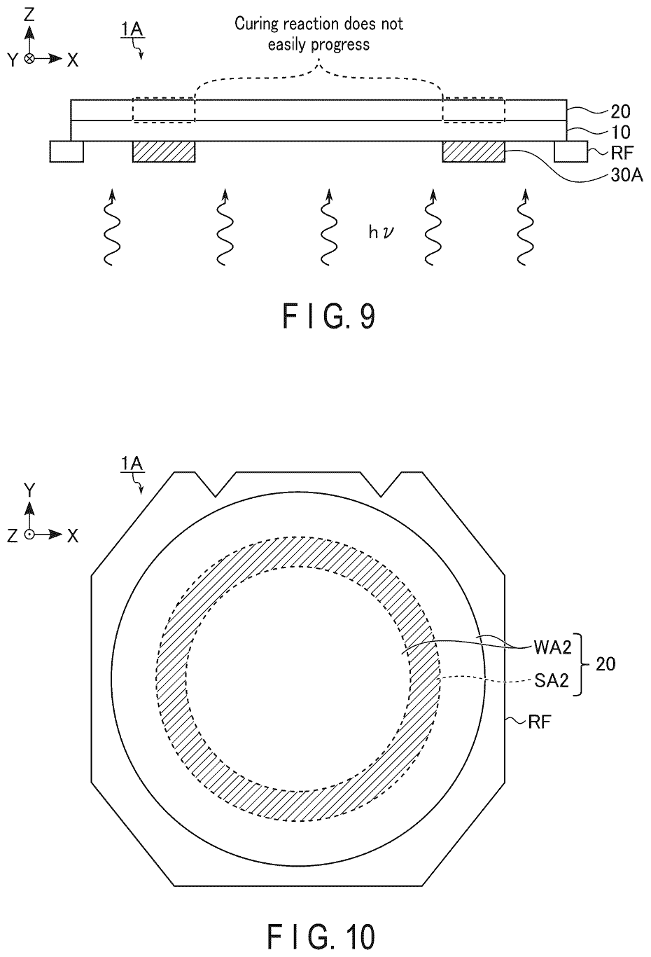

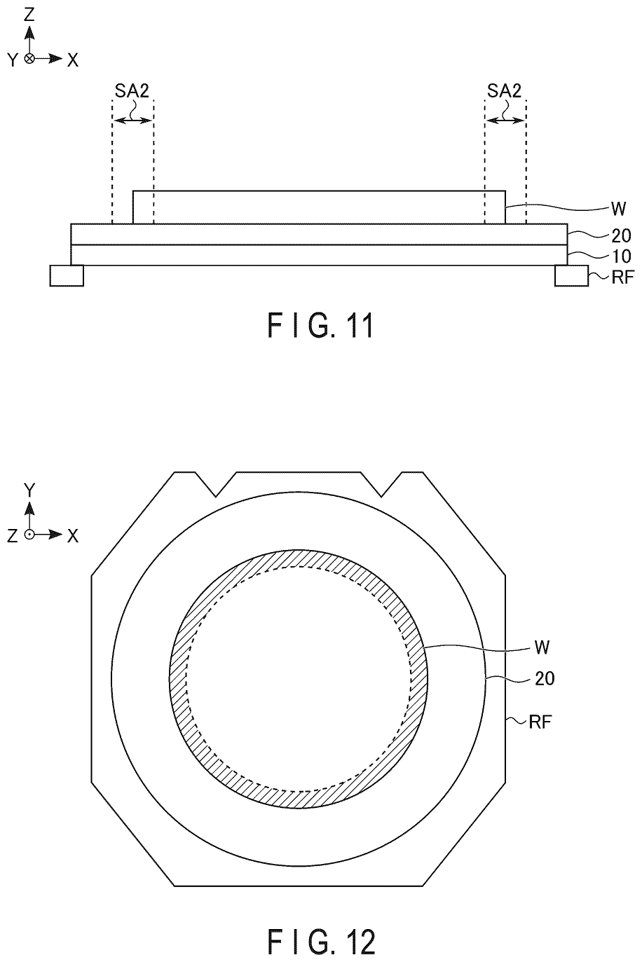

Next, a manufacturing method of a semiconductor device using the dicing tape 1A according to the modification is described with reference to FIG. 9, FIG. 10, FIG. 11 and FIG. 12. FIG. 9 and FIG. 11 are cross-sectional views for describing the manufacturing method of the semiconductor device using the dicing tape according to the modification. FIG. 9 and FIG. 11 correspond to the cross-sectional view of FIG. 7. FIG. 10 and FIG. 12 are top views for describing the manufacturing method of the semiconductor device using the dicing tape according to the modification.

To start with, like the embodiment, the dicing tape 1A is attached to the ring frame RF.

In addition, for example, as illustrated in FIG. 9, UV light irradiation, such as by a laser or a lamp, is executed from the back side of the dicing tape 1A attached to the ring frame RF, toward a region where the releasing film 30A is provided. Thereby, a curing reaction of the adhesive 20 progresses. At this time, in the fourth portion of the adhesive 20, which overlaps the releasing film 30A in the Z direction, light is shielded by the releasing film 30A, and thus the curing reaction does not easily progress. Thereby, as illustrated in FIG. 10, after the light irradiation, a portion WA2 with a low adhesive strength and a portion SA2 with a high adhesive strength are formed in the adhesive 20. The portion WA2 and the portion SA2 correspond to the third portion and the fourth portion of the adhesive 20, respectively. In FIG. 10, the portion SA2 is illustrated by hatching.

Then, after the light irradiation, for example, the releasing film 30A is peeled from the base 10. Note that in the modification, since the releasing film 30A is provided on the lower surface of the base 10, the releasing film 30A may not be peeled from the base 10 after the light irradiation.

Then, as illustrated in FIG. 11, the work W on which semiconductor devices are formed is fixed on the adhesive 20. At this time, like the embodiment, the work W is attached on the adhesive 20 such that the center of the work W (the center of the semiconductor substrate of the work W) corresponds to the center of the area from which the releasing film 30 is peeled. As described above, the length R4 is less than the length RW of the work W. Thereby, as illustrated in FIG. 12, the work W is fixed such that an outer peripheral portion of the work W, as viewed from above, comes in contact with the portion SA2 with the high adhesive strength in an annular shape. In FIG. 12, the outer peripheral portion of the work W, which is in contact with the portion SA2, is illustrated by hatching. In addition, the work W is fixed such that the portion inside the outer peripheral portion of the work W, as viewed from above, comes in contact with the portion WA2.

Further, like the embodiment, the work W fixed on the adhesive 20 as described above is diced by a blade or the like.

With modification, too, the same advantageous effects as in the embodiment are obtained.

### 3. Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method of a semiconductor device, comprising:
attaching a dicing tape to a ring frame, the dicing tape including a base, an adhesive provided on an upper surface of the base and including a material capable of changing in property by light irradiation, and a releasing film provided in such a manner as to overlap a portion of the adhesive as viewed from above;
executing light irradiation from below the base, thereby making an adhesivity of a first portion overlapping the releasing film as viewed from above, in an upper surface of the adhesive, different from an adhesivity of a second portion not overlapping the first portion, in the upper surface of the adhesive;
attaching a work piece to the adhesive by making a center of the work piece correspond to a center of an area where the releasing film is provided in the dicing tape; and
singulating a plurality of semiconductor devices by dicing the work piece.

2. The manufacturing method of the semiconductor device of claim 1, wherein
the dicing tape, in which the releasing film having a circular shape as viewed from above is provided on the upper surface of the adhesive, is used, and
an outside diameter of the releasing film is less than an outside diameter of the work piece.

3. The manufacturing method of the semiconductor device of claim 2, further comprising peeling the releasing film after the light irradiation is executed, before attaching the work piece to the adhesive.

4. The manufacturing method of the semiconductor device of claim 2, wherein
a reaction in which the adhesive changes in property at a time of the light irradiation is hindered by oxygen, and
the light irradiation is executed in an atmosphere in which oxygen is present.

5. The manufacturing method of the semiconductor device of claim 2, wherein the releasing film is provided such that the second portion has an annular shape surrounding the first portion, as viewed from above.

6. The manufacturing method of the semiconductor device of claim 2, wherein a difference between the outside diameter of the work piece and the outside diameter of the releasing film is 2 mm or more, and is 30 mm or less.

7. The manufacturing method of the semiconductor device of claim 1, wherein
the dicing tape, in which the releasing film having an annular configuration as viewed from above is provided on a lower surface of the adhesive, is used, and
an inside diameter of the releasing film is less than an outside diameter of the work piece.

8. The manufacturing method of the semiconductor device of claim 7, wherein the releasing film having a light-shielding property with respect to light used in the light irradiation is used.

9. The manufacturing method of the semiconductor device of claim 1, wherein light irradiation is executed from below the base, thereby making the adhesivity in the second portion higher than the adhesivity in the first portion.

10. The manufacturing method of the semiconductor device of claim 7, wherein an outside diameter of the releasing film is greater than the outside diameter of the work piece.

11. The manufacturing method of the semiconductor device of claim 10, wherein a difference between the outside diameter of the work piece and the inside diameter of the releasing film is 4 mm or more.

12. A dicing tape used to fix a work piece at a time of dicing the work piece, the dicing tape comprising:
a base;
an adhesive provided on an upper surface of the base and including a material capable of changing in property by light irradiation; and
a releasing film provided on a lower surface of the base, wherein
the releasing film has an annular configuration as viewed from above.

13. The dicing tape of claim 12, wherein the releasing film has a light-shielding property with respect to light in the light irradiation.
